(19) United States
(12) Patent Application Publication
(10) Pub. No.: US 2014/0306593 A1
(43) Pub. Date: Oct. 16, 2014

(54) HOUSING AND LATCHING MECHANISM

(71) Applicants: HON HAI PRECISION INDUSTRY CO., LTD., New Taipei (TW); Fu Tai Hua Industry (Shenzhen) Co., Ltd., Shenzhen (CN)

(72) Inventor: HAI-TAO GONG, Shenzhen (CN)

(21) Appl. No.: 13/902,869

(22) Filed: May 27, 2013

(30) Foreign Application Priority Data
Apr. 15, 2013 (CN) 2013101291974

(51) Int. Cl. H05K 5/02

(52) U.S. Cl. CPC H05K 5/0221
USPC 312/326

(57) ABSTRACT

A housing includes a main chassis defining a recess, a front panel, and a latching mechanism releasably securing the front panel to the main chassis. The latching mechanism includes a latching member, a latch and spring assembly connecting the latching member to the main chassis, an actuating member, a resilient member. The latching member includes a main body slidably received in the recess and at least one elastic jaw protruding radially outwardly from the main body. The latch and spring assembly includes a hook for latching the latching member within the recess and an elastic member for ejecting the latching member. The actuating member is slidably connected to the front panel and includes at least one barb. The resilient member is configured to apply a force to the actuating member for pulling the actuating member away from the main chassis.

### TECHNICAL FIELD

The present disclosure relates to a housing with a main chassis, a front panel, and a latching mechanism releasably securing the front panel to the main chassis.

### DESCRIPTION OF RELATED ART

Personal computers use storage devices, such as floppy disc drives, CDROM drives, DVD drives and hard disk drives, and other modules, which can be upgraded or replaced by a user. Generally, these devices are accessible from a removable front panel of the personal computer housing, often called a bezel. Generally, the personal computer housing includes a main chassis defining grooves and the front panel integral with latches received in the grooves, which constitutes a latching mechanism for securing the bezel to the main chassis. Although the latching mechanisms can satisfy basic requirements, a housing utilizing a new latching mechanism is still desired.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a housing with a main chassis and a front panel according to an exemplary embodiment.

FIG. 2 is an exploded, isometric view the housing of FIG. 1.

FIG. 3 is similar to FIG. 2, but viewed from a reverse perspective and with the main chassis detached.

FIG. 4 is a cross-sectional view of the housing, cutting along line IV-IV of FIG. 1.

FIG. 5 is an isometric view of the housing of FIG. 1, showing the front panel rotated away from the main chassis.

### DETAILED DESCRIPTION

Embodiments of the present disclosure are now described in detail, with reference to the accompanying drawings.

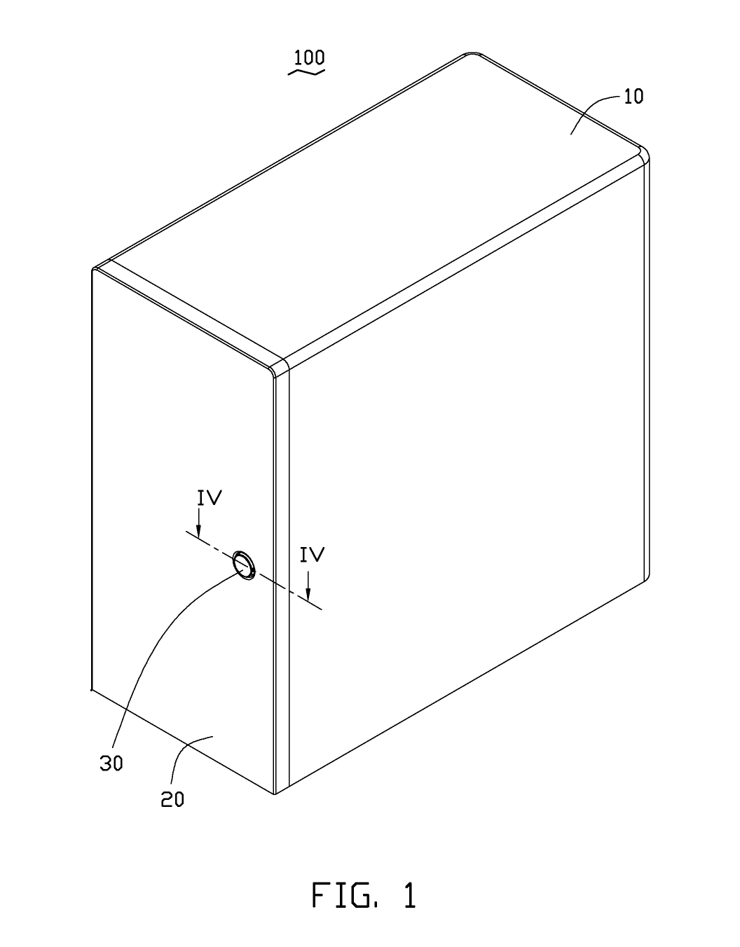

FIG. 1 is the housing 100 of the exemplary embodiment. The housing 100 includes a rectangular main chassis 10, a front panel 20, and a latching mechanism 30 releasably securing the front panel 20 to the main chassis 10.

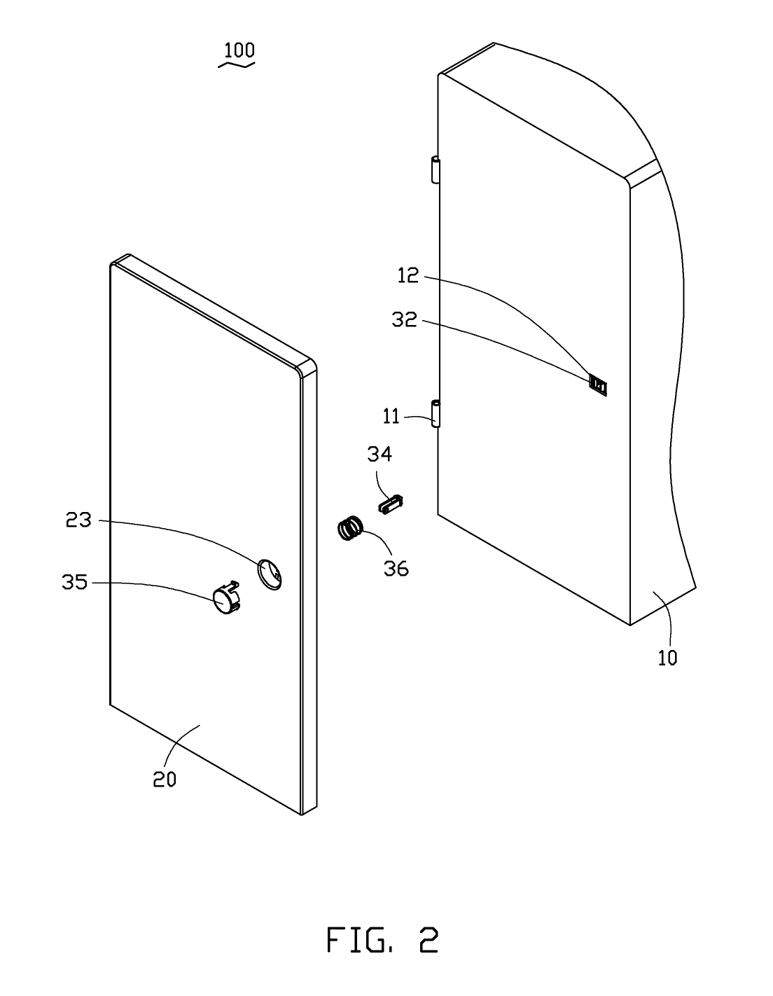

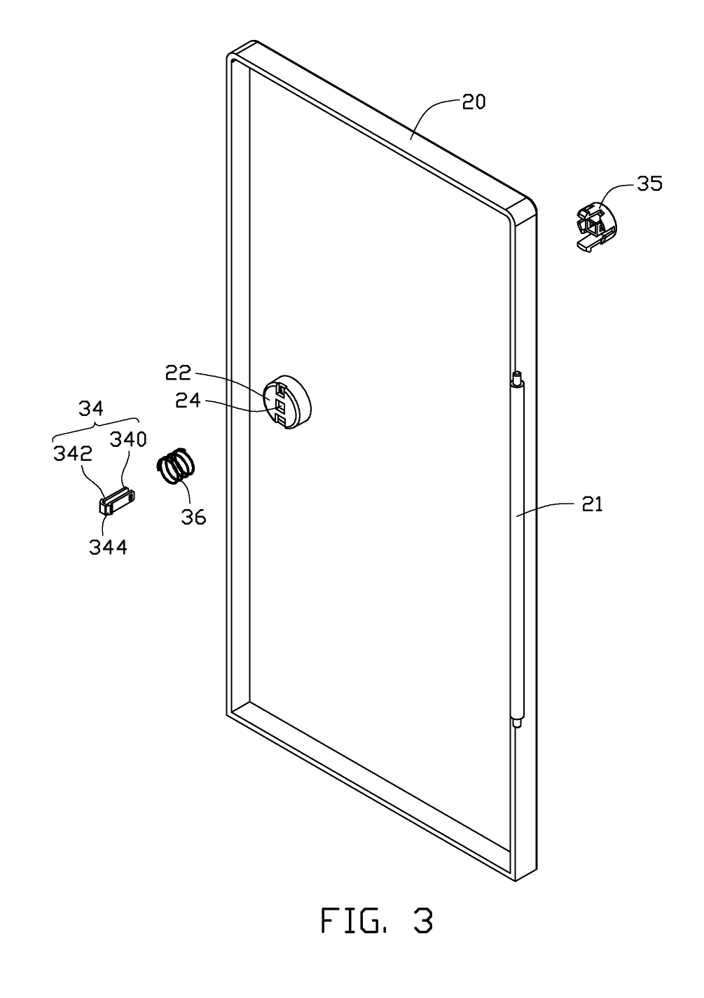

FIGS. 2-3 shows that the main chassis 10 includes a first hinge portion 11 and a mounting hole 12 is defined therein. The front panel 20 includes a second hinge portion 21 rotatably connected to the first hinge portion 11 and a protruding portion 22 protruding toward the mounting hole 12 of the main chassis 10. A button hole 23 is defined in the protruding portion 22. The button hole 23 opens toward a direction away from the main chassis 10. In addition, a through hole 24 is defined in a bottom of the button hole 23.

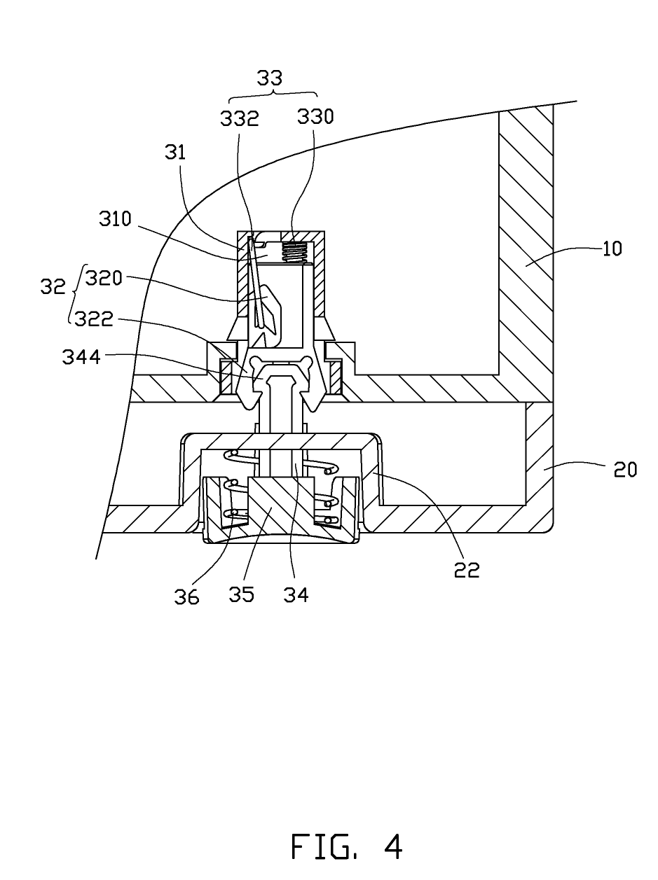

FIG. 4 shows that the latching mechanism 30 includes a case 31, a latching member 32, a latch and spring assembly 33, an actuating member 34, a button 35, and a resilient member 36. The case 31 is fixedly installed in the mounting hole 12 of the main chassis 10 and defines a recess 310 facing the front panel 20. The latching member 32 includes a rectangular main body 322 movably received in the recess 310 and two elastic jaws 322 protruding radially outwardly from the main body 320.

The latch and spring assembly 33 includes an elastic member 330 positioned between the case 31 and the latching member 32 and a hook 332. When the latching member 32 is pushed into the recess 310 of the case 31 and then is released, a sidewall of the recess 310 urges the elastic jaws 322 to elastically deform toward each other, the latching member 32 moves back a little till getting caught by the hook 332, thereby preventing the elastic jaws 322 from protruding out from the recess 310. When the latching member 32 is further pushed into the recess 310 and then is released, the hook 332 releases the latching member 32, thereby allowing the compressed elastic member 330 to eject the latching member 32, thus, the elastic jaws 322 protrude out from the recess 310 and return to their original positions. Such a latch and spring assembly 33 is well known in the art, such as a structure incorporating the movable member and the spring that connects the hanger to the base in U.S. Pat. No. 8,238,118, which is herein incorporated by reference.

The actuating member 34 includes a first end 340 extending through the through hole 24 of the front panel 20, an opposite second end 342, and two barbs 344 protruding from opposite sides of the second end 342. The button 35 is slidably received in the button hole 23 of the front panel 20 and fixed to the first end 340 of the actuating member 34.

The resilient member 36 is used to apply a force to the actuating member 34 for pulling the actuating member 34 away from the main body 10. In the embodiment, the resilient member 36 is a spring coil coiled around the actuating member 34 and compressed between the button 35 and the front panel 20.

FIGS. 1 and 4 show that when the front panel 20 is rotated toward the main chassis 10, the second end 342 of the actuating member 34 first pushes the latching member 32 into the recess 310 of the case 31. The hook 332 latches the latching member 32 within the recess 310, and the elastic jaws 322 are deformed toward each other for engaging the barbs 344 of the actuating member 34, thereby securing the front panel 20 to the main chassis 10.

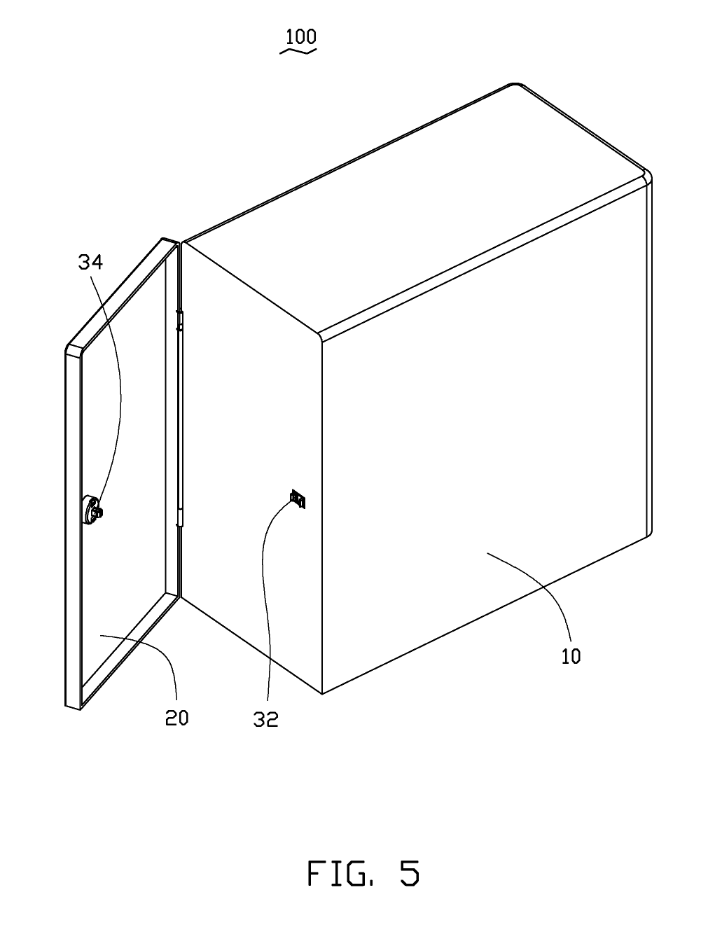

FIG. 5 shows that when the button 36 is pressed toward the main chassis 10 and the actuating member 34 further pushes the latching member 32 into the recess 310. The hook 332 releases the latching member 32, allowing the compressed elastic member 330 to eject the latching member 32, and then the elastic jaws 322 return to their original positions and disengage from the barbs 344 of the actuating member 34, thereby releasing the front panel 20 from the chassis 10.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A housing comprising:
a main chassis defining a recess;
a front panel; and
a latching mechanism comprising:
a latching member comprising a main body slidably received in the recess and a plurality of elastic jaws protruding radially outwardly from the main body;
a latch and spring assembly connecting the latching member to the main chassis, the latch and spring assembly comprising a hook for latching the latching member within the recess and an elastic member for ejecting the latching member;
an actuating member slidably connected to the front panel and comprising at least one barb; and
a resilient member configured to apply a force to the actuating member for pulling the actuating member away from the main chassis;
wherein when the front panel is attached to the main chassis, the actuating member firstly pushes the latching member into the recess, causing the hook to latch the latching member within the recess, and a sidewall of the recess urges the jaws to elastically deform toward each other for engaging the at least one barb of the actuating member, thereby securing the front panel to the main chassis; and
when the actuating member further pushes the latching member into the recess, the actuating member causes the hook to release the latching member, the compressed elastic member ejects the latching member out, and the jaws returns to an original position and disengages from the at least one barb of the actuating member, thereby releasing the front panel from the main chassis.

2. The housing as described in claim 1, wherein the main chassis comprises a first hinge portion, and the front panel comprises a second hinge portion rotatably coupled to the first hinge portion.

3. The housing as described in claim 1, wherein the main chassis defines a mounting hole, and the latching mechanism comprises a case defining the recess and fixedly installed in the mounting hole.

4. The housing as described in claim 1, wherein the front panel comprises a protruding portion protruding toward the main chassis, the protruding portion defines a button hole opening toward a direction away from the main chassis and a through hole in a bottom of the button hole for the extension of the actuating member, and the latching mechanism further comprises a button slidably received in the button hole and fixed to the actuating member.

5. The housing as described in claim 4, wherein the resilient member is compressed between the protruding portion and the actuating member.

6. The housing as described in claim 5, wherein the resilient member is a spring coil coiled around the actuating member with opposite ends abutting against the front panel and the button.

7. A latching mechanism for releasably securing a first member to a second member, the second member defining a recess, the latching mechanism comprising:
a latching member comprising a main body slidably received in the recess of the second member and a plurality of elastic jaws protruding radially outwardly from the main body;
a latch and spring assembly connecting the latching member to the main chassis, the latch and spring assembly comprising a hook for latching the latching member within the recess and an elastic member for ejecting the latching member;
an actuating member slidably connected to the first member and comprising at least one barb; and
a resilient member configured to apply a force to the actuating member for pulling the actuating member away from the second member;
wherein when the first member is attached to the second member, the actuating member firstly pushes the latching member into the recess, causing the hook to latch the latching member within the recess, and a sidewall of the recess urges the at least one jaw to elastically deform toward each other for engaging the at least one barb of the actuating member, thereby securing the first member to the second member; and
when the actuating member further pushes the latching member into the recess, the actuating member causes the hook to release the latching member, the compressed elastic member ejects the latching member out, and the at least one jaw return to an original position and disengages from the at least one barb of the actuating member, thereby releasing the first member from the second member.

8. The latching mechanism as described in claim 7, further comprising a button mounted in the first member and fixed to the actuating member.

9. The latching mechanism as described in claim 8, wherein the resilient member is compressed between the first member and the button.

10. The latching mechanism as described in claim 9, wherein the resilient member is a spring coil coiled around the actuating member with opposite ends abutting against the first member and the button.
